(19) United States
(12) Patent Application Publication
(10) Pub. No.: US 2025/0349711 A1
(43) Pub. Date: Nov. 13, 2025

(54) RESISTANCE AND CAPACITANCE TUNING IN BEOL REGIONS

(71) Applicant: International Business Machines Corporation, Armonk, NY (US)

(72) Inventors: Ruilong Xie, Niskayuna, NY (US); Lawrence Alfred Clevenger, Saratoga Springs, NY (US); Brent Alan Anderson, Jericho, VT (US); Nicholas Anthony Lanzillo, Wynantskill, NY (US); Reinaldo Vega, Mahopac, NY (US); Albert Manhee Chu, Nashua, NH (US)

(21) Appl. No.: 18/659,277

(22) Filed: May 9, 2024

(51) Int. Cl. H01L 23/522; H01L 21/768

(52) U.S. Cl. CPC H01L 23/5228; H01L 21/76816; H01L 21/76885; H01L 23/5222; H01L 23/5226

(57) ABSTRACT

A semiconductor integrated circuit (IC) device includes a bottom wire level, a top wire level, a first region with a first vertical dimension between the bottom wire level and the top wire level, and a second region with a second vertical dimension between the bottom wire level and the top wire level that is less than the first vertical dimension. The discrepancy in the vertical dimensions between wiring levels in different regions of the semiconductor IC device may provide desired or optimized capacitance and/or resistance metrics therein and may increase overall semiconductor integrated circuit (IC) device performance.

### BACKGROUND

In the semiconductor IC device fabrication industry, there are three sections referred to in a build: front end of line (FEOL) section, back end of line (BEOL) section, and the section that connects those two together, the middle of line (MOL). The FEOL is made up of devices, e.g., transistors, the BEOL is made up of interconnects and wiring, and the MOL includes interconnects between the FEOL and BEOL and material to prevent the diffusion of BEOL conductive material(s) to the FEOL devices.

The BEOL section is the portion of the semiconductor IC device fabrication where the wiring of the semiconductor IC device is formed. The embodiments of the disclosure are directed to relatively tuning the resistance of one or more wires within a conductive level and/or capacitance between wires within different conductive levels within two different regions of the BEOL section.

### SUMMARY

In an embodiment of the disclosure, a semiconductor integrated circuit (IC) device is presented. The semiconductor IC device includes a bottom wire level and a top wire level, a first region with a first vertical dimension between the bottom wire level and the top wire level, and a second region with a second vertical dimension between the bottom wire level and the top wire level that is less than the first vertical dimension.

In an embodiment of the disclosure, another semiconductor IC device is presented. The semiconductor IC device includes a first region and a second region. The first region includes a first bottom wire, a first top wire, and a first via directly connected to the first bottom wire and directly connected to the first top wire. The second region includes a second bottom wire, a second top wire, and a second via directly connected to the second bottom wire and directly connected to the second top wire. A first vertical dimension between the first bottom wire and the first top wire is greater than a second vertical dimension between the second bottom wire and the second top wire.

In another embodiment of the disclosure, a semiconductor IC device fabrication method is presented. The method includes forming a first bottom wire and a second bottom wire, forming a first via upon the first bottom wire, and forming a second via upon the second bottom wire. The method further includes forming a first interlayer dielectric (ILD) upon the first bottom wire and the second bottom wire around the first and second vias. The method further includes recessing the first ILD around the second via and maintaining the first ILD around the first via. The method further includes forming a first top wire upon the first via and forming a second top wire wrapped around the second via. As the second top wire is wrapped around the second via, the second via may be inset within the second top wire.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of an illustrative semiconductor IC device that includes tuned or different resistances and/or capacitances of associated with wire(s) within different regions of a BEOL section, according to one or more embodiments of the disclosure.

FIG. 2 through FIG. 11 depict various fabrication structure cross-section views of an illustrative semiconductor IC device that is formed to include tuned or different resistances and/or capacitances of associated wire(s) within different regions of a BEOL section, according to one or more embodiments of the disclosure.

FIG. 12 depicts a cross-section view of an illustrative semiconductor IC device that includes tuned or different resistances and/or capacitances of associated with wire(s) within different regions of a BEOL section, according to one or more embodiments of the disclosure.

FIG. 13 depicts a illustrative method to fabricate a semiconductor IC device that includes tuned or different resistances and/or capacitances of associated with wire(s) within different regions of a BEOL section, according to one or more embodiments of the disclosure

### DETAILED DESCRIPTION

The embodiments of the present disclosure relate to fabrication methods and resulting structures for semiconductor IC devices. More specifically, the present disclosure relates to a semiconductor IC device that includes a BEOL section with different regions or areas. Within one area, the dimension between wiring levels is greater that a similar dimension between wiring levels in another different area. In this manner, by changing this relative dimension between wiring levels, the capacitance between wiring levels can be tuned within the different BEOL section regions or areas. Further, within the first area, a vertical dimension of an upper wire is greater than a similar dimension of the upper wire in the second area. In this manner, by changing this relative dimension of the upper wire, the resistance of the upper wires can be tuned within the different BEOL section regions or areas.

The BEOL section is the portion of IC fabrication where the individual devices (e.g., transistors, capacitors, resistors, etc.) become interconnected with wiring on the semiconductor IC device, e.g., the metallization layer or layers of a wafer. The BEOL section includes contacts, insulating layers (dielectrics), metal levels, and bonding sites for chip-to-package connections. In the BEOL section, part of the fabrication stage contacts (pads), interconnect wires, vias and dielectric structures are formed. For modern IC processes, more than one metal layers may be added in the BEOL section. Respective wires within the BEOL section may be electrically connected to the one or more regions of the FEOL devices via a direction connection, or indirect connection via respective MOL contacts. The BEOL section can include one or more interconnect dielectric material layers and can contain conductive wires embedded therein. The BEOL section can include “x” numbers of conductive levels, wherein “x” is an integer starting from 1. The BEOL section may further contain conductive pads that may be used to connect the semiconductor IC device to an external and/or higher-level structure, such as a chip carrier, motherboard, or the like.

The flowcharts and cross-sectional diagrams in the drawings illustrate a method of fabricating a semiconductor IC device, such as a processor, filed programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

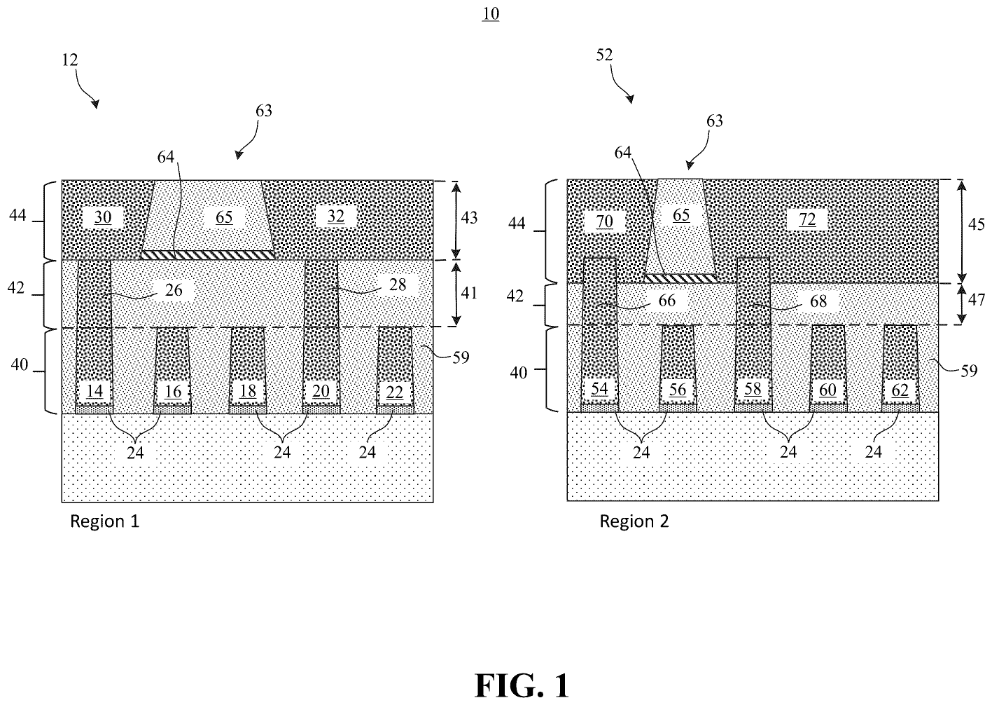

Referring now to the figures, FIG. 1 depicts a cross-sectional view of an illustrative semiconductor integrated circuit (IC) device 10. The semiconductor IC device 10 includes a bottom wire level 40 and a top wire level 44. The semiconductor IC device 10 further includes a first region 12 with a first vertical dimension 41 between the bottom wire level 40 and the top wire level 44. The semiconductor IC device 10 further includes a second region 52 with a second vertical dimension 47 between the bottom wire level 40 and the top wire level 44 that is less than the first vertical dimension 41.

The discrepancy between the first vertical dimension 41 and the second vertical dimension 43 in different regions 12, 52 of the semiconductor IC device 10 may provide for desired or optimized capacitance and/or resistance metrics therein and may increase overall semiconductor integrated circuit (IC) device 10 performance. For example, in region 12 the capacitance between the bottom wire level 40 and the top wire level 44 may be reduced relative to such capacitance in region 52. Similarly, in region 52 the resistance of a wire 70, 72 within the top wire level 44 may be lower relative to such resistance of a wire 30, 32 within the top wire level 44 in region 12.

In an example, a top surface of the top wire level 44 in the first region 12 is coplanar with a top surface of the top wire level 44 in the second region 52. As such, manufacturing defects due to material buildup or as a result of material deposition over undulating surface(s) may be minimized.

In an example, a bottom surface of the top wire level 44 in the second region 52 is below a bottom surface of the top wire level 44 in the first region 12. For example, a dimension 43 of the top wire level 44 in region 12 is smaller than a dimension 45 of the top wire in region 52. As a result, the volume of respective wires 70, 72 may be increased relative to the volume of wires 30, 32 and may resultantly allow for the wires 70, 72 in the second region 52 to have a relatively lower resistance. Likewise, the capacitance between the top wire level 44 and the bottom wire level 40 in the second region 52 may be increased relative to the capacitance between the top wire level 44 and the bottom wire level 40 in the first region 12.

In an example, the semiconductor IC device 10 includes a via level 42 that directly connects the bottom wire level 40 to the top wire level 44. The via level 42 is generally a level that includes vias. For example, via level 42 may include vias 26, 28 in the first region 12 and vias 66, 68 in the second region that may directly connect respective wires in the bottom wire level 40 to the top wire level 44.

In an example, a first vertical dimension 41 of the via level 42 in the first region 12 is greater than a vertical dimension 47 of the via level 42 in the second region 52. The vertical dimension 47 of the via level 42 may be reduced not due to respective vertical heights of the vias 66, 68 in the second region 52, but rather, due to the bottom surface of the top wire level 44 in the second region 52 being below the bottom surface of the top wire level 44 in the first region 12. Therefore, as depicted, respective top surfaces of vias 66, 68 may be substantially horizontally coplanar with respective top surfaces of vias 26, and 28 even though the first vertical dimension 41 of the via level 42 in the first region 12 is greater than the vertical dimension 47 of the via level 42 in the second region 52.

In an example, respective wires 70, 72 within the top wire level 44 wrap around respective vias 66, 68 within the via level 42 within the second region 52. Therefore, as depicted, respective top surfaces of vias 66, 68 may be substantially horizontally coplanar with respective top surfaces of vias 26, and 28 and the bottom surface of the top wire level 42 may be below the top surfaces of vias 26, and 28 in the second region 52. As a result of the respective wires 70, 72 wrapping around respective vias 66, 68, the vias 66, 68 may be inset within the respective wires 70, 72. For example, the top surfaces of the vias 66, 68 may be internal to the respective wires 70, 72 (e.g., between the top and bottom surfaces of the respective wires 70, 72). Resultingly, respective vias 66, 68 may be inset within the respective wires 70, 72 within the second region 52.

In an example, the vertical heights of the vias 26, 28, 66, 68 may be substantially the same. However, due to the vias 66, 68 being inset within the respective wires 70, 72, the vertical dimension of via level 42 within the second region 52 may be smaller than the vertical dimension of the via level 42 within the first region 12.

In an example, adjacent wires 14, 16, 18, 20, 22, 54, 56, 58, 60, and 62 within the bottom wire level 40 are horizontally separated by a first dielectric material 59. The first dielectric material 59 may be an interlayer dielectric in which the wires 14, 16, 18, 20, 22, 54, 56, 58, 60, and 62 and the vias 26, 28, 66, and 68 may be formed by, for example, single or double damascene fabrication techniques.

In an example, adjacent wires 30, 32 or adjacent wires 70, 72 within the top wire level 44 are horizontally separated by a separation block 62 comprising an etch stop layer 64 that is directly upon the via level 42. The etch stop layer 64 in the second region 52 may be below the etch stop layer 64 in the first region 12 due to the first dielectric material 59 being recessed only in the second region 52 prior to the deposition of the etch stop layer 64.

In an example, the separation block 62 further comprises a second dielectric material 65 directly upon the etch stop layer 64. The second dielectric material 65 may be an interlayer dielectric in which the wires 30, 32, 70, 72 may be formed.

In an example, the second dielectric material is different relative to the first dielectric material. For example, the second dielectric material may be chosen to achieve certain capacitance threshold(s) between the different wires 30, 32, 70, 72 in the top wire level 44 that the first dielectric material could not provide. For example, the second dielectric material may have a higher dielectric constant relative to the first dielectric material.

In an embodiment of the disclosure, a semiconductor IC device 10 is presented. The semiconductor IC device 10 includes a first region 12 and a second region 52. The first region 12 includes a first bottom wire 20, a first top wire 32, and a via 28 directly connected to the first bottom wire 20 and directly connected to the first top wire 32. The second region 52 includes a second bottom wire 58, a second top wire 72, and a second via 68 directly connected to the second bottom wire 58 and directly connected to the second top wire 72. A first vertical dimension 41 between the first bottom wire 20 and the first top wire 32 is greater than a second vertical dimension 47 between the second bottom wire 58 and the second top wire 72.

The discrepancy between the first vertical dimension 41 and the second vertical dimension 47 in different regions 12, 52 of the semiconductor IC device 10 may provide for desired or optimized capacitance and/or resistance metrics therein and may increase overall semiconductor IC device 10 performance. For example, in region 12 the capacitance between the bottom wire 20 and the top wire 32 may be reduced relative to the capacitance between the bottom wire 58 and the top wire 72 in region 52. Similarly, in region 52 the resistance of a top wire 72 may be lower relative to such resistance of the top wire 32 in region 12.

In an example, a top surface of the first top wire 32 is coplanar with a top surface of the second top wire 72. For example, the first top wire 32 and the second top wire 72 may be a part of the same top wire level 44, which may be subjected to a planarization fabrication process, such as a chemical mechanical polish (CMP) which may cause the first top wire 32 to be coplanar with the top surface of the second top wire 72. As such, manufacturing defects due to material buildup or as a result of material deposition over undulating surface(s) may be minimized.

In an example, a bottom surface of the second top wire 72 is below a bottom surface of the first top wire 32. As a result, the volume of the second top wire 72 may be increased relative to the volume of the first top wire 32 and may resultantly allow the second top wire 72 to have a relatively lower resistance. Likewise, the capacitance between the second top wire 72 and the second bottom wire 58 in the second region 52 may be increased relative to the capacitance between the bottom wire 20 and the top wire 32 in the first region 12.

In an example, the second top wire 72 directly contacts a top surface of the second via 68 and directly contacts one or more side surface(s) of the second via 68. This may result from the due to the first dielectric material 59 in which the second via 68 is formed being recessed only in the second region 52 thereby exposing an upper portion of the second via 68. Subsequently, the second top wire 72 may be formed around the exposed portion of the second via 68. Resultingly, the second via 68 may be inset within the respective wires 70, 72 within the second region 52.

In an example, the second top wire 72 wraps around the second via 68. For example, the second top wire 72 may be formed around a previously exposed upper portion of the second via 68, thereby wrapping around the second via 68.

In an example, the first region 12 further includes one or more additional first top wires 30 with respective bottom surface(s) that are coplanar with a bottom surface of the first top wire 32. For example, the first top wire 32 and the one or more additional first top wires 30 may be a part of the same top wire level 44 formed on a planar via level 42 in region 12.

In an example, the second region 52 further comprises one or more additional second top wires 70 with respective bottom surface(s) that are coplanar with a bottom surface of the second top wire 72. For example, the second top wire 72 and the one or more additional second top wires 70 may be a part of the same top wire level 44 formed on a planar via level 42 around respective second vias 66, 68 in region 52.

In an example, a first isolation block 62 separates the first top wire 32 from one or more additional first top wires 30 and a second isolation block 62 separates the second top wire 72 from one or more additional second top wires 70. The first separation block 62 includes an first etch stop layer 64 and a first dielectric material 65 upon the first etch stop layer 64 and the second separation block 62 includes an second etch stop layer 64 and a second dielectric material 65 upon the second etch stop layer 64. These etch stop layers and the dielectric material layers may be the layers in which the first top wire 32, the one or more additional first top wires 30, the second top wire 72, and the one or more additional second top wires 70 may be formed.

In an example, the second etch stop layer is below the first etch stop layer. This may result from the due to the first dielectric material 59 in which the second via 68 is formed being recessed only in the second region 52 thereby lowering the surface of the first dielectric material 59 in the second region 52 prior to the formation of a etch stop blanket layer blanket layer that which forms the etch stop layers 64. Therefore, the etch stop layer 64 in the second region 52 is below the etch stop layer 64 in the first region 12.

In another embodiment of the present disclosure, a semiconductor IC device fabrication method is presented. The method includes forming a first bottom wire 20 and a second bottom wire 58 and forming a first via 28 upon the first bottom wire 20 and forming a second via 68 upon the second bottom wire 58. The method further includes forming a first dielectric material 59 upon the first bottom wire 20 and the second bottom wire 58 around the first via 28 and the second via 68. The method further includes recessing the first dielectric material 59 around the second via 68 and maintaining the first dielectric material 59 around the first via 28. The method further includes forming a first top wire 32 upon the first via 28 and forming a second top wire 72 wrapped around the second via 68. Resultingly, the second via 68 may be inset within the second top wire 72.

The geometry and wrapping of the second top wire 72 around the second via 68 may provide for desired or optimized capacitance and/or resistance metrics. For example, by controlling the degree of the recessing the first dielectric material 59 around the second via 68 while keeping the top surface of the top wire 72 coplanar with the other wires 70, 32, 30 in the same wiring level 44, the capacitance between the bottom wire 20 and the top wire 32 may be reduced relative to the capacitance between the bottom wire 58 and the top wire 72. Similarly, the resistance of the top wire 72 may be lower relative to such resistance of the top wire 32.

In another embodiment of the present disclosure, another instance of a semiconductor IC device 10 is presented. The semiconductor IC device 10 includes the first region 12 that has the first bottom wire 20, the first top wire 32, and the first via 28 directly connected to a top surface of the first bottom wire 20 and directly connected to a bottom surface of the first top wire 32. The semiconductor IC device 10 further includes the second region 52 that has the second bottom wire 58, the second top wire 72, and the second via 68 directly connected to a bottom surface of the second bottom wire 58 and inset within the second top wire 72.

The second via 68 being inset with the second top wire 72 may provide for desired or optimized capacitance and/or resistance metrics. For example, by forming the second top wire 72 around the second via 68, while keeping the top surface of the top wire 72 coplanar with the other wires 70, 32, 30 in the same wiring level 44, the capacitance between the bottom wire 20 and the top wire 32 may be reduced relative to the capacitance between the bottom wire 58 and the top wire 72. Similarly, the resistance of the top wire 72 may be lower relative to such resistance of the top wire 32.

In another embodiment of the present disclosure, another instance of a semiconductor IC device 10 is presented. The semiconductor IC device 10 includes the bottom wire level 40 and the top wire level 44. The semiconductor IC device 10 further includes the first region 12 that has the first bottom wire 20 within the bottom wire level 40 and the first top wire 32 within the top wire level 44. The semiconductor IC device 10 further includes the second region 52 that has the second bottom wire 58 within the bottom wire level 40, the second top wire 72 within the top wire level 44, and the via 68 connected to the second bottom wire 58 and inset within the second top wire 72.

The second via 68 being inset with the second top wire 72 may provide for desired or optimized capacitance and/or resistance metrics. For example, by forming the second top wire 72 around the second via 68, while keeping the top surface of the top wire 72 coplanar with the other wires 70, 32, 30 in the same wiring level 44, the capacitance between the bottom wire 20 and the top wire 32 may be reduced relative to the capacitance between the bottom wire 58 and the top wire 72. Similarly, the resistance of the top wire 72 may be lower relative to such resistance of the top wire 32.

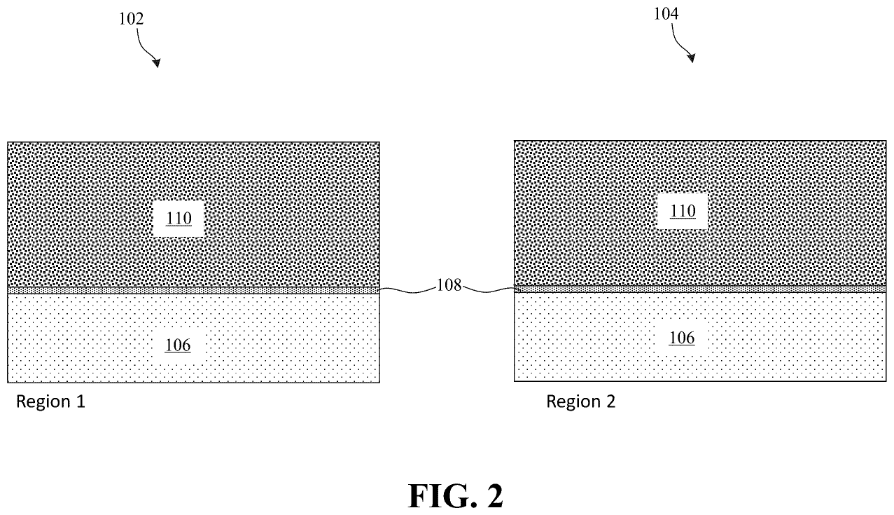

FIG. 2 depicts an initial fabrication structure cross-section view of an illustrative semiconductor IC device 100 that is formed to include tuned or different resistances and/or capacitances of associated with wire(s) within different regions of a BEOL section. At the present fabrication stage, semiconductor IC device 100 includes underlayment section 106, conductive liner 108, and conductive layer 110 within at least a first region 102 and a second region 104.

The underlayment section 106 may be a FEOL section or MOL section and the conductive liner 108 and conductive layer 110 may be initial material(s) of a BEOL section. The FEOL section may include a semiconductor substrate and a plurality of microdevices formed upon or therefrom. For example, several transistors may be formed over the substrate. Each transistor may have a source, drain, and gate. The transistors may be a FinFET, Gate all around (GAA) FET, Forksheet FET, or the like. The MOL section may include one or more dielectric material(s) formed over the plurality of microdevices and respective conductive contacts formed within the dielectric material(s) that are directly coupled with one or more regions of the plurality of microdevices. The one or more dielectric material(s) of the MOL section may prevent the diffusion of conductive material(s) between the FEOL section and the BEOL section.

The BEOL section may be built upon the MOL section and may include the wiring of the semiconductor IC device 100. The BEOL section may include passivation layers, conductive wiring levels, conductive interconnect levels between conductive wiring levels, and/or bonding pads for chip-to-package connections. In examples, the BEOL section is a frontside BEOL section formed on the frontside of the semiconductor IC device 100.

The BEOL section may be formed by depositing a conductive liner 108 upon the underlayment section 106. For example, the conductive liner 108 may be formed upon a top surface of the one or more dielectric material(s) and upon respective top surfaces of the conductive contacts of the MOL section. The conductive liner 108 may be formed as a blanket layer upon the top frontside surface of the entire semiconductor IC device 100. The conductive liner 108 may be formed using a sputtering, spin on, plating, ALD, or other deposition technique. The conductive liner 108 may serve as a barrier layer and may be composed of, for example, a titanium, a titanium alloy, or the like.

The conductive layer 110 may be formed upon the top surface of the conductive liner 108. The conductive layer 110 may be formed as a blanket layer and may be formed to a thickness to establish a vertical height of a bottom wiring level 40, as depicted in FIG. 1, when a single damascene fabrication process is utilized to form the bottom wire level 40. Alternatively, as depicted, the conductive layer 110 may be formed as a blanket layer and may be formed to a thickness to establish a vertical height of a bottom wiring level 40 and an associated via level 42, when a subtractive metal etch process is utilized to form the bottom wire level 40 and via level 42.

Conductive layer 110 may be formed using a sputtering, spin on, plating, ALD, or other deposition technique. In embodiments, the conductive layer 110 may be, for example, ruthenium, tungsten, copper, nickel, nickel alloys, copper alloys, etc. Subsequently, the top surface of the conductive layer 110 may be planarized by a planarization technique, such as a CMP.

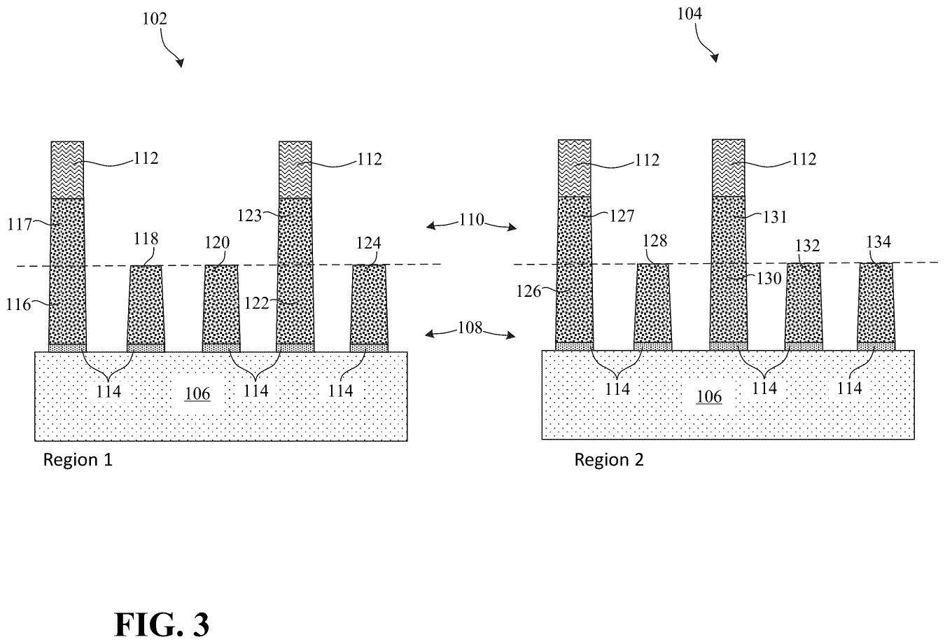

FIG. 3 depicts a fabrication structure cross-section view the semiconductor IC device 100 that is formed to include tuned or different resistances and/or capacitances of associated with wire(s) within different regions of the BEOL section. At the present fabrication stage, the conductive layer 110 and the conductive liner 108 may be patterned to form bottom wires 116, 118, 120, 122, 124, 126, 128, 130, 132, and 134 with a respective bottom liner 114 thereunder, collectively referred to as bottom wires, may be formed in the first region 102 and the second region 104.

The bottom wires may be formed by the same or shared lithography and etch process(es), or sequential lithography and etch processes. In such process(es), a mask 112 may be deposited upon the conductive layer 110 and patterned. The associated openings in the mask 112 may expose the portion(s) of the underlying conductive layer 110 that are to be removed while other protected portions of conductive layer 110 may be protected and retained.

Subsequently, the bottom wires may be formed by a subtractive removal technique, such as a dry etch process to remove the undesired portions of the conductive layer 110 and conductive liner 108 that are unprotected by the patterned mask 112. The etch that forms the bottom wires may be selective to the material(s) of the underlayment section 106. For example, the bottom wires may be formed by an etch that utilizes the one or more dielectric(s) of the underlayment section 106 as the etch stop.

The respective portions of the conductive layer 110 and conductive liner 108 that remain may resultantly form the bottom wires 116, 118, 120, 122, 124, 126, 128, 130, 132, and 134 and may resultantly form the respective bottom liner 114 under each respective bottom wire.

The bottom liner 114 may be directly coupled to a MOL contact (not shown) within the underlayment section 106. Therefore, each of the bottom wires 116, 118, 120, 122, 124, 126, 128, 130, 132, and 134 may be electrically connected to an associated region(s) of respective microdevices within the FEOL section. The bottom wires may be a part of respective conductive pathways that may be used to provide and/or to route respective signals (e.g., input signal, output signal, logic high signal, logic low signal, etc.) to the microdevices within the FEOL section and/or may be used to provide electric potential (e.g., VDD, VSS, etc.) to the microdevices within the FEOL section. For clarity, the depicted bottom wires 116, 118, 120, 122, 124, 126, 128, 130, 132, and 134 and the respective bottom liner 114 under each respective bottom wire may be in the lowest conductive wire level (e.g., metal level zero) within the semiconductor IC device 100. Alternatively, these bottom wires may be in higher conductive wire relative to the lowest conductive wire level but still serve as bottom wires (e.g., below) relative to top wires generally there above.

For clarity, particular vias 117, 123, 127, 131 are depicted in the illustrated cross-section. In this example, the bottom wires 116, 118, 120, 122, 124, 126, 128, 130, 132, and 134, the respective bottom liner 114 under each respective bottom wire, and the associated via(s) upon the bottom wires may be generically referred to herein as bottom wires. For clarity, at the present fabrication stage, a portion of the mask 112 may be retained upon each of the bottom wires. Vias 117, 123, 127, 131, may be formed by lithography and etch techniques, similar to those described herein, followed by metal recess, or the like.

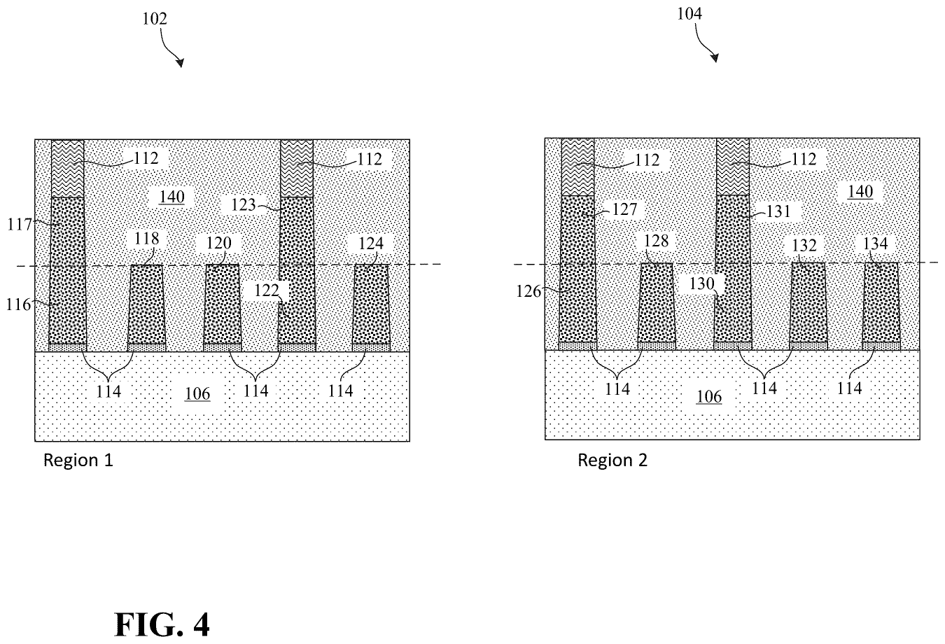

FIG. 4 depicts a fabrication structure cross-section view the semiconductor IC device 100 that is formed to include tuned or different resistances and/or capacitances of associated with wire(s) within different regions of the BEOL section. At the present fabrication stage, a first interlayer dielectric (ILD) 140 may be formed over the bottom wires and over the retained mask 112 portions.

The ILD 140 may be formed by depositing a dielectric material upon the bottom wires, over the underlayment section 106, and over the retained mask 112 portions upon the bottom wires. The dielectric material may be porous silicates, carbon doped oxides, silicon dioxides, silicon nitrides, silicon oxynitrides, or other dielectric materials. Any appropriate deposition technique for forming the ILD 140 can be utilized and may be, for example, CVD, PECVD, ALD, flowable CVD, spin-on dielectrics, PVD, or the like. Subsequently, excess ILD 140 may be removed by a planarization technique, such as a CMP. As a result, respective top surfaces of the retained mask 112 portions and the ILD 140 may be substantially horizontal and coplanar.

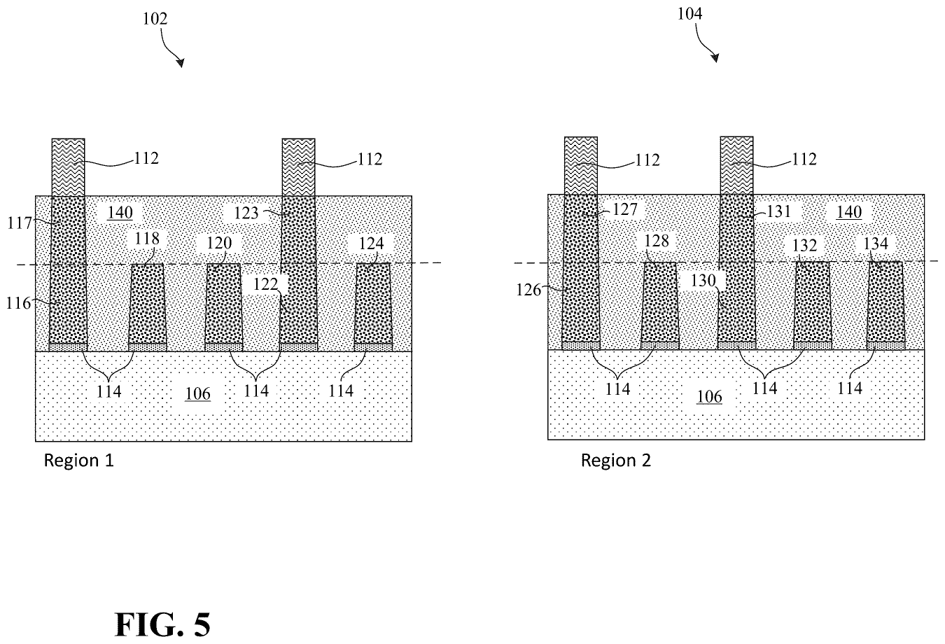

FIG. 5 depicts a fabrication structure cross-section view the semiconductor IC device 100 that is formed to include tuned or different resistances and/or capacitances of associated with wire(s) within different regions of the BEOL section. At the present fabrication stage, the ILD 140 may be partially recessed in the first region 102 and in the second region 104.

The ILD 140 may be partially recessed by a subtractive removal technique such as a wet etch and may generally expose the mask 112 portions retained upon the bottom wires. The etch to partially recess the ILD 140 may be selective to the material of the mask 112.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material compared to a second material by a ratio of 2:1 or greater, e.g., 5:1, 10:1 or 20:1.

The etch to partially recess the ILD 140 may be timed or otherwise controlled to remove the material of the ILD 140 stopping at a substantially horizontal plane that is coplanar with one or more respective bottom surfaces of the mask 112 portion(s).

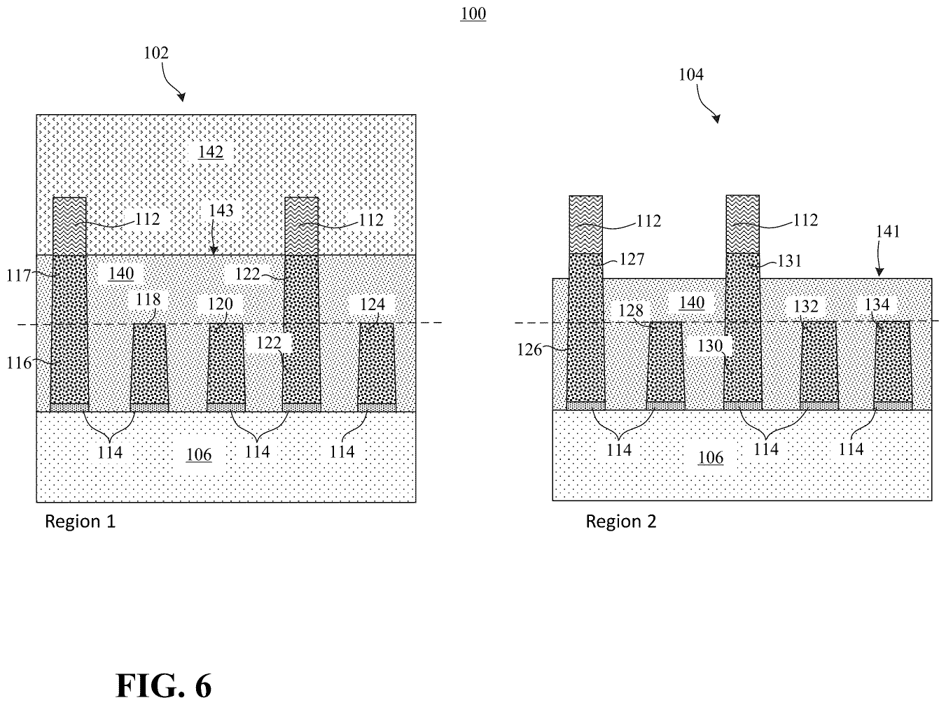

FIG. 6 depicts a fabrication structure cross-section view the semiconductor IC device 100 that is formed to include tuned or different resistances and/or capacitances of associated with wire(s) within different regions of the BEOL section. At the present fabrication stage, a mask 142 may be deposited within the first region 102 and the first ILD 140 may be further recessed in the second region 104.

The mask 142 may be deposited over the semiconductor IC device 100 in both the first region 102 and in the second region 104 and subsequently removed only in the second region 104, by a selective etch. The mask 142 can be composed of any suitable temporary mask material(s), such as a dielectric material, organic planarization layer (OPL), or the like. The mask 142 may be generally retained in the first region 102 so as to protect the underling mask 112 portion(s) and the first ILD 140 in the first region 102.

The mask 142 may be patterned to generally remove the mask 142 in only the second region 104 by the same or shared lithography and etch process(es), or sequential lithography and etch processes. In such process(es), the mask 142 may be deposited upon the conductive layer 110 and patterned. The associated opening(s) in the mask 112 may expose the second region 104 while the first region 102 may be protected and retained. The etch that removes the material of the mask 142 may be selective to the material of the mask 112 portions and may utilize the first ILD 140 in the second region 104 as an etch stop.

Subsequently, the first ILD 140 in the second region 104 may be further recessed by a subtractive removal technique to remove the first ILD 140 in the second region 104 to expose respective upper portions of the vias that connect to the bottom wires 126, 128, 130, 132, 134, etc. within the second region 104 (e.g., via 127, via 131). The etch that recesses the first ILD 140 in the second region 104 may be selective to the material(s) of the vias that connect to the bottom wires 126, 128, 130, 132, 134, etc. within the second region 104. The etch may be timed or otherwise controlled to limit the depth of the recess of the first ILD 140 in the second region 104 so that an upper surface 141 of the first ILD 140 is both below respective top surfaces of vias that connect to the bottom wires 126, 128, 130, 132, 134, etc. and above bottom surfaces of these vias that connect to the bottom wires 126, 128, 130, 132, 134, etc. within the second region 104 (e.g., via 127, via 131). As such, the recessing of the first ILD 140 in the second region 104 generally exposes at least respective portions of such vias. Further, subsequent to the recessing of the first ILD 140 in the second region 104, the top surface 141 of the first ILD 140 in the second region 104 is below a top surface 143 of the first ILD 140 in the first region 102.

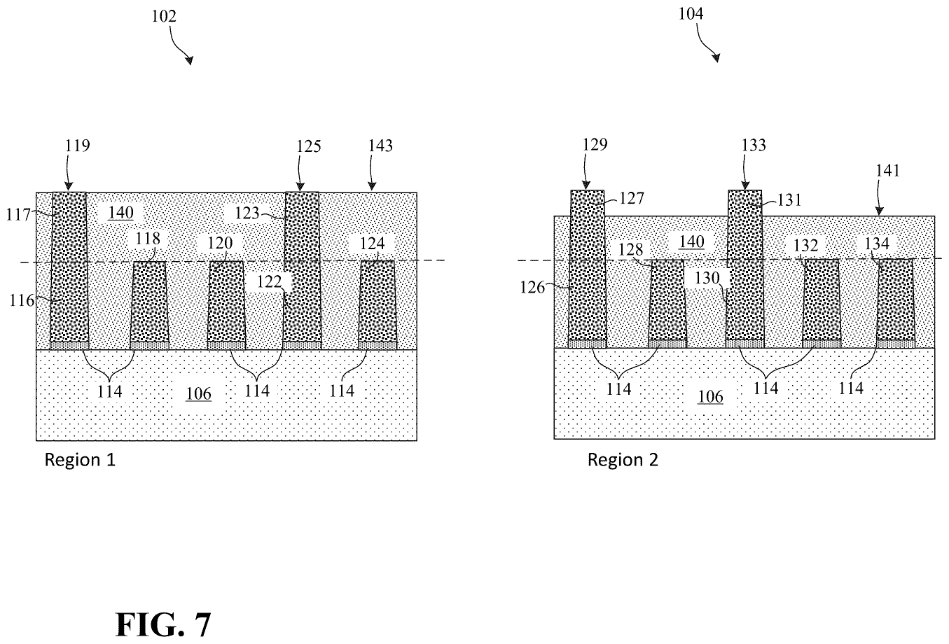

FIG. 7 depicts a fabrication structure cross-section view the semiconductor IC device 100 that is formed to include tuned or different resistances and/or capacitances of associated with wire(s) within different regions of the BEOL section. At the present fabrication stage, the mask 142 and the mask 112 portions may be removed in the first region 102.

The mask 142 and the mask 112 portions may be removed in the first region 102 by the same or shared lithography and etch process(es), or sequential lithography and etch processes. For example, the mask 142 may be removed by a first etch and the mask 112 portions may be removed in a second etch. The one or more etch(es) that removes the mask 142 and the mask 112 portions may be selective to the material of the first ILD 140 and may utilize the first ILD 140 in the first region 102 as an etch stop. When the material of the mask 142 and the mask 112 portions are composed of an OPL, the mask 142 and the mask 112 portions may be removed by an OPL ash, or the like.

For clarity, in the depicted illustration, the semiconductor IC device 100 may have a substantially horizontal and coplanar top surface in the first region 102. For example, a top surface 119 of via 117, a top surface 125 of via 123, and the top surface 143 of the first ILD 140 may be substantially and/or horizontally coplanar. Further, in the depicted illustration, due to the top surface 141 of the first ILD 140 being recessed or below the top surface 143 and thereby exposing the vias 127, 131, the semiconductor IC device 100 may have nonplanar top surface in the second region 104. For example, a top surface 129 of via 127 and a top surface 133 of via 131 is above the top surface 141 of the first ILD 140 in the second region 104.

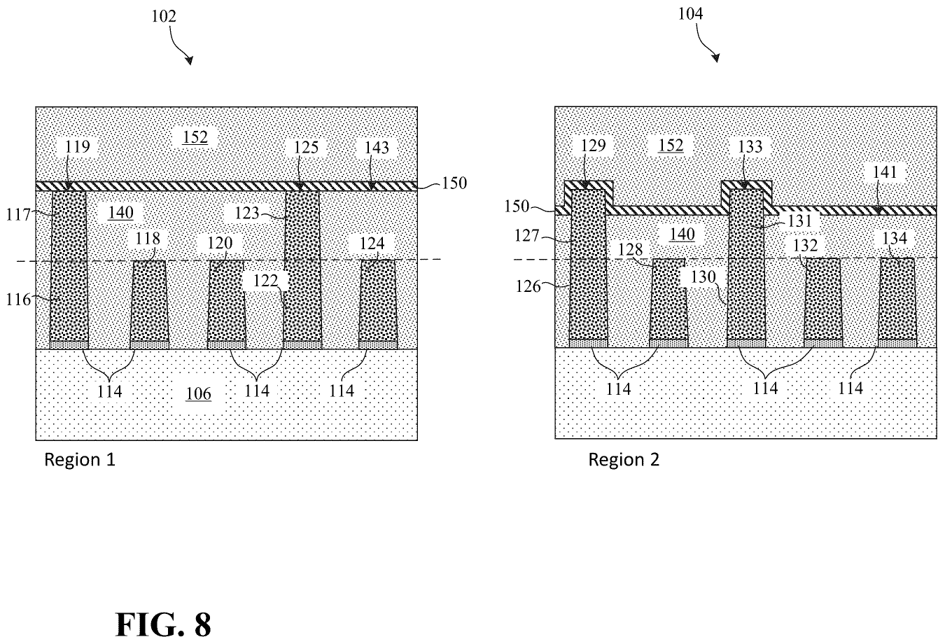

FIG. 8 depicts a fabrication structure cross-section view the semiconductor IC device 100 that is formed to include tuned or different resistances and/or capacitances of associated with wire(s) within different regions of the BEOL section. At the present fabrication stage, an etch stop layer 150 may be formed in the first region 102 and in the second region 104 and a second ILD 152 may be formed on the etch stop layer 150.

The etch stop layer 150 may be formed by depositing a dielectric material upon the first ILD 140 and upon the respective top surface of the vias that are coplanar with the first ILD 140 in the first region 102 and may further be formed by depositing the dielectric material upon the first ILD 140 and upon and around the exposed regions of the respective vias that are above the first ILD 140 in the second region 104.

The dielectric material of the etch stop layer 150 may be composed of a dielectric that has etch selectivity with at least the second ILD 152. For example, the first ILD 140 may be composed of a silicon oxide and the etch stop layer 150 may be composed of a silicon nitride. Any appropriate deposition technique for forming the etch stop layer 150 can be utilized.

In the illustrated example, the etch stop layer 150 may be formed directly upon the top surface 119 of via 117, directly upon the top surface 125 of via 123, and directly upon the top surface 143 of the first ILD 140 in the first region 102 and may be further formed directly upon the exposed region of via 127, directly upon the expose region of the via 131, and directly upon the top surface 141 of the first ILD 140 in the second region 104.

The second ILD 152 may be formed by depositing a dielectric material upon the etch stop layer 150. The dielectric material of the second ILD 152 generally has etch selectivity to the material of the etch stop layer 150. The dielectric material of the second ILD 152 may be the same dielectric material compared to the first ILD 140. Any appropriate deposition technique for forming the second ILD 152 can be utilized. Subsequently, excess second ILD 152 may be removed by a planarization technique, such as a CMP. As a result, the top surface of second ILD 152 may be substantially horizontal and coplanar. As such, the top surface of the second ILD 152 may be coplanar in both the first region 102 and the second region 104.

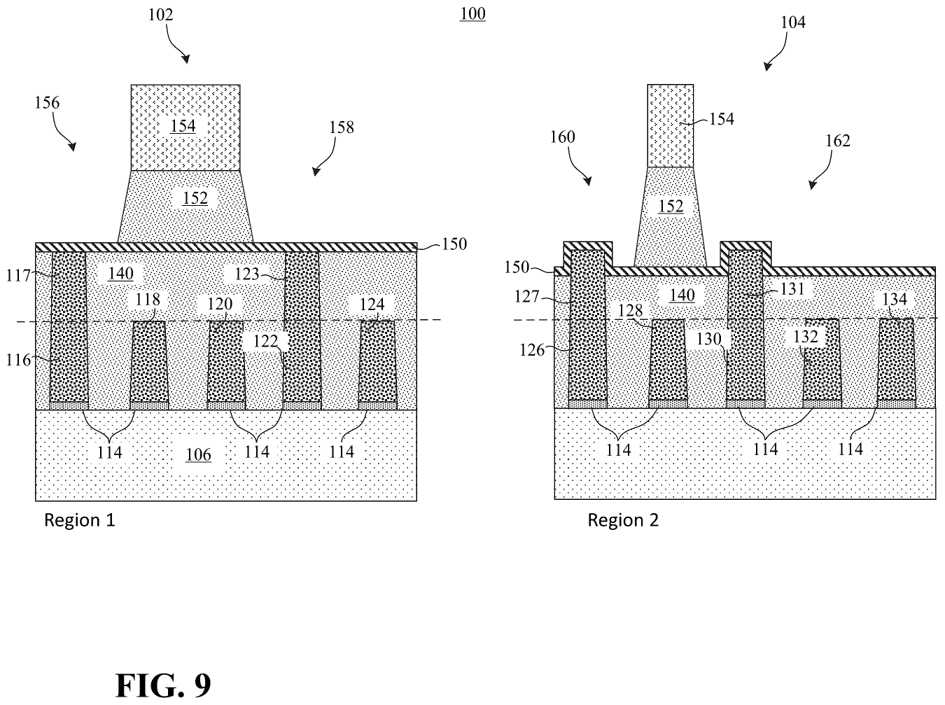

FIG. 9 depicts a fabrication structure cross-section view the semiconductor IC device 100 that is formed to include tuned or different resistances and/or capacitances of associated with wire(s) within different regions of the BEOL section. At the present fabrication stage, top wire openings 156 and 158 may be formed within the second ILD 152 in the first region 102 and top wire openings 160 and 162 may be formed within the second ILD 152 in the second region 104.

The top wire openings 156, 158, 160, and 162 may be formed by the same or shared lithography and etch process(es), or sequential lithography and etch processes. In such process(es), a mask 154 may be deposited upon the second ILD 152 and patterned. The associated openings in the mask 154 may expose the portion(s) of the underlying second ILD 152 that are to be removed while other protected portions of second ILD 152 may be protected and retained.

The top wire openings 156, 158, 160, and 162 may be further formed by a subtractive removal technique, such as a wet etch that utilizes an etchant to remove the undesired portions of the second ILD 152 that are unprotected by the patterned mask 154. The etch that forms the top wire openings 156, 158, 160, and 162 within the second ILD 152 may utilize the etch stop layer 150 as the etch stop.

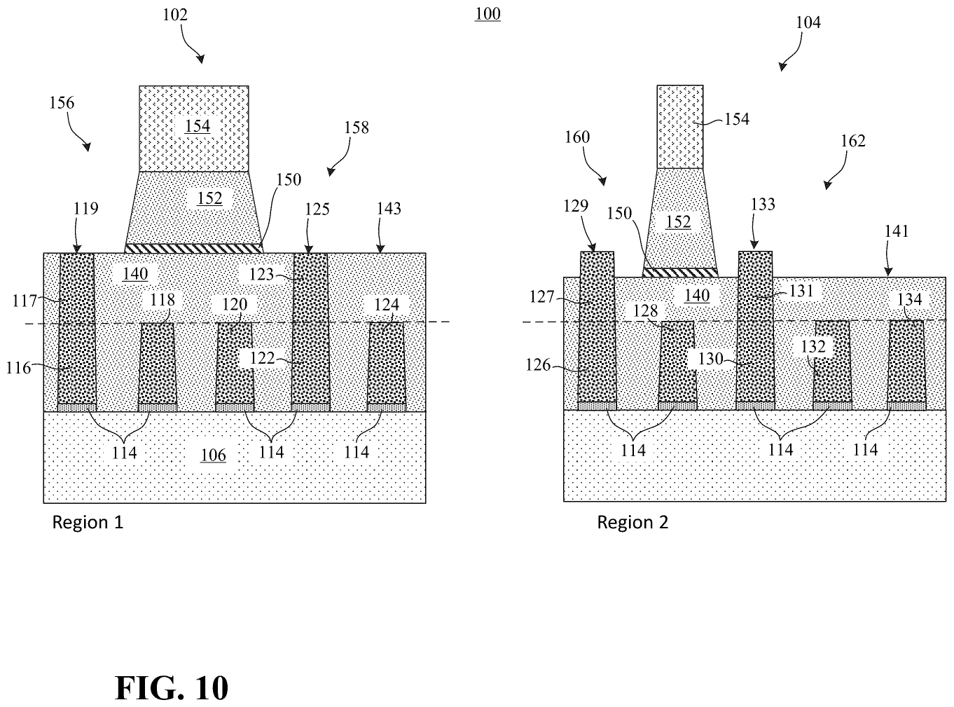

FIG. 10 depicts a fabrication structure cross-section view the semiconductor IC device 100 that is formed to include tuned or different resistances and/or capacitances of associated with wire(s) within different regions of the BEOL section. At the present fabrication stage, the etch stop layer 150 may be removed from within the top wire openings 156, 158, 160, and 162.

The etch stop layer 150 may be removed from within the top wire openings 156, 158, 160, and 162 by a subtractive removal technique, such as a wet etch that utilizes an etchant to remove the undesired portions of the etch stop layer 150 that are within the top wire openings 156, 158, 160, and 162. The etch that removes the etch stop layer 150 may be selective to the material of the second ILD 152 and of the vias 117, 123, 127, 131 and may utilize the first ILD 140 as an etch stop.

The removal of the etch stop layer 150 from within the top wire openings 156, 158 may generally expose the top surface 143 of the first ILD 140, the top surface 119 of the via 117, and the top surface 125 of the via 123 in region 102. The removal of the etch stop layer 150 from within the top wire openings 160, 162 may generally expose the top surface 141 of the first ILD 140, the top surface 129 and sidewall(s) of the exposed portion of the via 117, and the top surface 133 and sidewall(s) of the exposed portion of the via 131 in region 104.

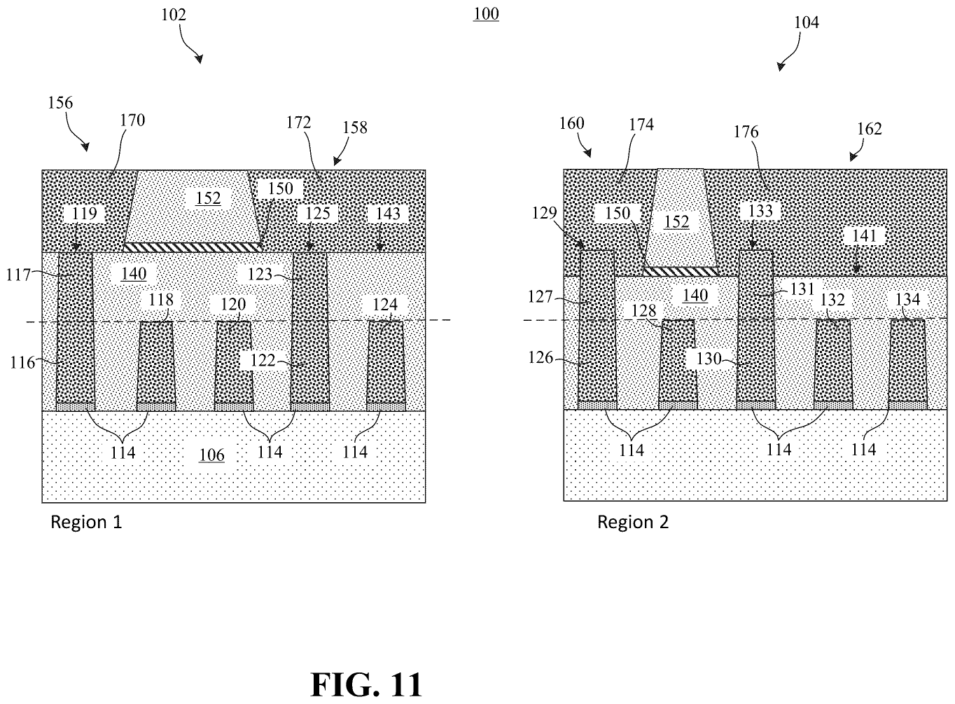

FIG. 11 depicts a fabrication structure cross-section view the semiconductor IC device 100 that is formed to include tuned or different resistances and/or capacitances of associated with wire(s) within different regions of the BEOL section. At the present fabrication stage, top wires 170, 172, 174, and 176 are formed in the top wire openings 156, 158, 160, and 162, respectively.

Respective top wires 170, 172, 174, and 176 may be formed within respective top wire openings 156, 158, 160, and 162 directly against via 117, via 123, via 127, and via 131 by depositing conductive material, such as metal, therein. In an example, top wires 170, 172, 174, and 176 may be formed by depositing a conductive liner, such as Ni, NiPt or Ti, etc. within respective top wire openings 156, 158, 160, and 162 directly upon the first ILD 140 and directly against via 117, via 123, via 127, and via 131, respectively. For example, top wire 170 may be formed directly upon the top surface 143 of the first ILD 140 and the top surface 119 of the via 117 in region 102, top wire 172 may be formed directly upon the top surface 143 of the first ILD 140 and the top surface 125 of the via 123 in region 102, top wire 174 may be formed directly upon the top surface 141 of the first ILD 140 and the top surface 129 of the via 127 in second region 104, and top wire 176 may be formed directly upon the top surface 141 of the first ILD 140 and the top surface 133 of the via 131 in second region 104.

In this example, top wires 170, 172, 174, and 176 may be further formed by depositing an adhesion liner, such as TiN, TaN, etc. upon the liner, and by depositing a conductive fill, such as Cu, Co, W, Al, Ru, W, etc. upon the adhesion liner.

Subsequently, a planarization process, such as a CMP, may remove excess top wire 170, 172, 174, and 176 material. As a result, the respective top surfaces of top wires 170, 172, 174, and 176 and the second ILD 152 may be substantially horizontal and/or substantially coplanar.

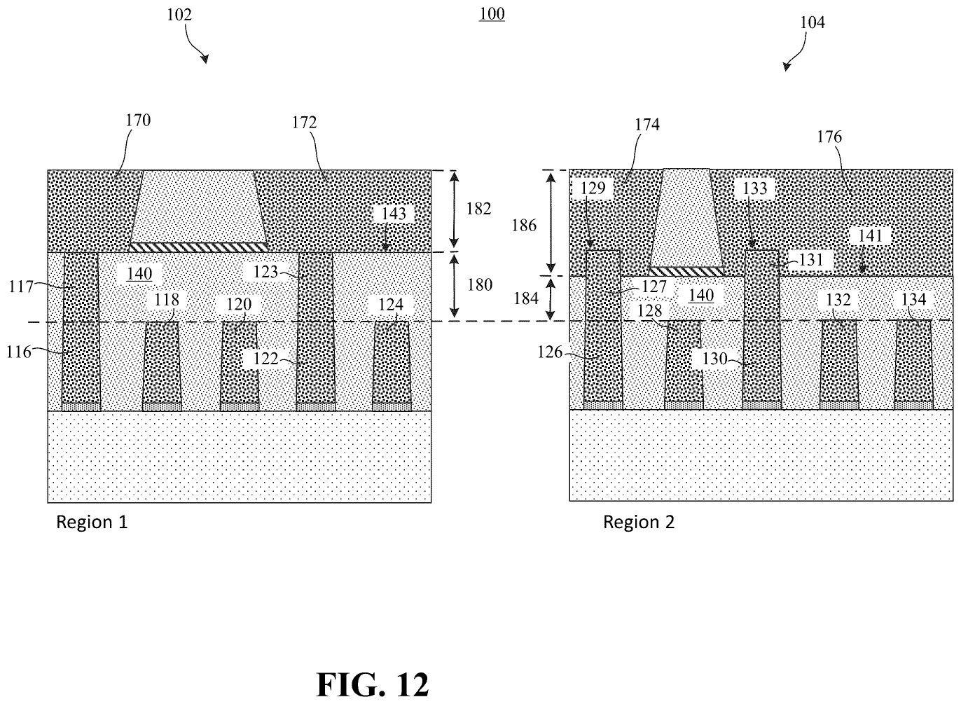

FIG. 12 depicts a fabrication structure cross-section view the semiconductor IC device 100 that is formed to include tuned or different resistances and/or capacitances of associated with wire(s) within different regions of the BEOL section. For example, in the first region 102, the capacitance between the bottom wire 124 and the top wire 172 may be reduced relative to the capacitance between the bottom wire 134 and the top wire 176 due to the degree to which the top surface 141 of the first ILD 140 in the second region 104 is below the top surface 143 of the first ILD 140 in the first region 102 in the second region 104. Similarly, in the first region 102 the resistance of the top wire 172 may be lower relative to the resistance of the top wire 176 in region 104 due to the degree in which the top surface 141 of the first ILD 140 in the second region 104 is below the top surface 143 of the first ILD 140 in the first region 102.

FIG. 12 further depicts a first vertical dimension 180 between bottom wires 116, 118, 120, 122, 124 and the top wires 170, 172 in the first region 102 that is greater than a second vertical dimension 184 between the bottom wires 126, 128, 130, 132, and 134 and the top wires 174 and 176 in the second region 104. Similarly, FIG. 12 further depicts, a first vertical height 182 of the top wires 170, 172 in the first region 102 that is less than a second vertical height 186 of the top wires 174 and 176 in the second region 104.

For clarity, though the BEOL section of the semiconductor IC device 100 is depicted to include two wiring levels (i.e., a bottom wiring level in which the bottom wires 116, 118, 120, 122, 124, 126, 128, 130, 132, and 134 reside and a top wiring level in which the top wires 170, 172, 174, and 176 reside) and a via level (i.e., the via level in which the vias 117, 123, 127, 131 reside) that connects the two wiring levels, the BEOL section of the semiconductor IC device 100 may include more wiring levels (e.g., ten or more wiring levels) which a via level connecting respective levels thereof.

The semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

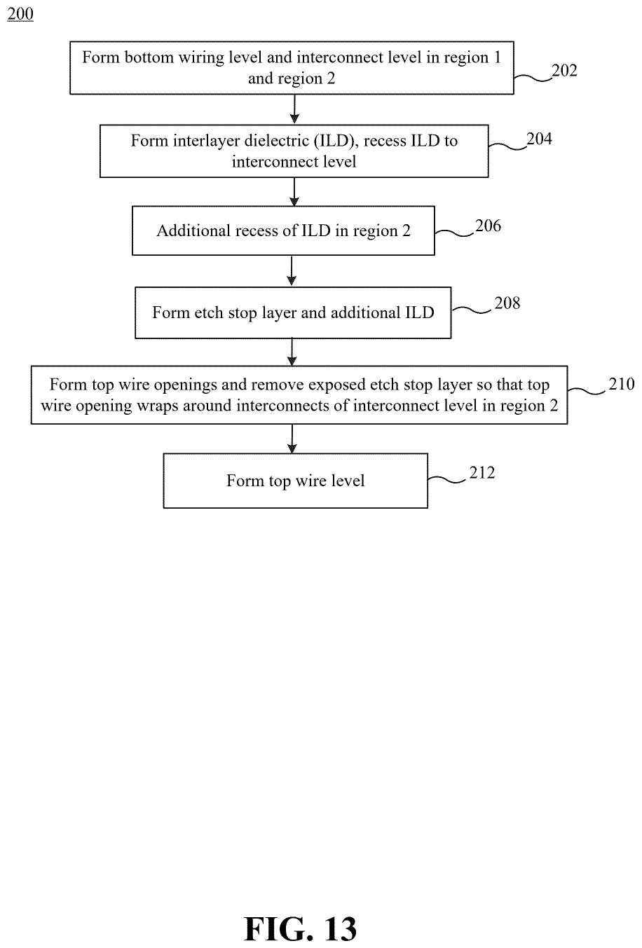

FIG. 13 depicts a flow diagram illustrating a method 200 to fabricate a semiconductor IC device, such as semiconductor IC device 100. The depicted fabrication operations of method 200 are illustratively depicted and described above with reference to one or more of FIG. 2 through FIG. 11 of the drawings, which describe the fabrication of semiconductor IC device 100, though the fabrication operations described in method 200 may be used to fabricate other types of semiconductor IC devices. The method 200 depicted herein is illustrative. There can be many variations to the diagram or operations described therein without departing from the spirit of the embodiments. For instance, the operations can be performed in a differing order, or operations can be added, deleted, or modified.

At block 202, method 200 may begin with forming a bottom wiring level and an associated interconnect level upon the bottom wiring level in a first region and in a second region of the semiconductor IC device. For example, a first bottom wire 122 and a second bottom in the first region 102 is formed in the first region 102 and a second bottom wire 130 is formed in the second region 104. Subsequently, a first via 123 is formed on the first bottom wire 122 in the first region 102 and a second via 131 is formed on the second bottom wire 130.

Method 200 may continue with forming an ILD and recessing the ILD to the interconnect level at block 204. For example, the first ILD 140 is formed upon the first bottom wire 122, upon the second bottom wire 130, upon the first via 123 is formed on the first bottom wire 122, and upon a second via 131. The ILD 140 may be recessed so that a top surface of the first ILD 140 is coplanar with the via level.

Method 200 may continue with further recessing the ILD in only the second region at block 206. For example, the first region 102 is protected by a mask and the second region 104 is exposed and the first ILD 140 is further recessed below the top surface of the via 131. Therefore, an upper portion of the via 131 is exposed by the recessing of the first ILD 140.

Method 200 may continue with forming an etch stop layer and an additional ILD at block 208. For example, an etch stop layer 150 may be formed upon the first ILD 140 and upon the first via 123 in the first region 102. The etch stop layer 150 may be also formed upon the first ILD 140 and upon and around the exposed portion of the second via 131 in the second region 104. Further, a second ILD 152 may be formed upon the etch stop layer 150.

Method 200 may continue with forming top wire openings and removing respective portions of the etch stop layer that are exposed by the top wire openings such that at least one top wire opening in the second region wraps around the interconnect level at block 210. For example, a top wire opening 158 is formed within the second ILD 152 and within the etch stop layer 150 that exposes the first via 123 in the first region 102 and a top wire opening 162 is formed within the second ILD 152 and within the etch stop layer 150 that wraps around the upper portion of the second via 131 in the second region 104.

Method 200 may continue with forming a top wiring level of respective top wires within the top wire openings at block 212. For example, a first top wire 172 may be formed within the top wire opening 158 upon the first via 123 and a second top wire 176 may be formed within the top wire opening 162 that wraps around the second via 131. Resultingly, the second via 131 may be inset within the second top wire 176.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a bottom wire level and a top wire level;
a first region with a first vertical dimension between the bottom wire level and the top wire level; and
a second region with a second vertical dimension between the bottom wire level and the top wire level that is less than the first vertical dimension.

2. The semiconductor IC device of claim 1, wherein a top surface of the top wire level in the first region is coplanar with a top surface of the top wire level in the second region.

3. The semiconductor IC device of claim 2, wherein a bottom surface of the top wire level in the second region is below a bottom surface of the top wire level in the first region.

4. The semiconductor IC device of claim 3, further comprising:
a via level that directly connects the bottom wire level to the top wire level.

5. The semiconductor IC device of claim 4, wherein a vertical height of the via level in the first region is greater than a vertical height of the via level in the second region.

6. The semiconductor IC device of claim 5, wherein respective wires, within the top wire level, wrap around respective vias within the via level within the second region.

7. The semiconductor IC device of claim 6, wherein adjacent wires within the bottom wire level are horizontally separated by a first dielectric material.

8. The semiconductor IC device of claim 7, wherein adjacent wires within the top wire level are horizontally separated by a separation block comprising an etch stop layer that is directly upon the via level.

9. The semiconductor IC device of claim 8, wherein the separation block further comprises a second dielectric material directly upon the etch stop layer.

10. The semiconductor IC device of claim 9, wherein the second dielectric material is different relative to the first dielectric material.

11. A semiconductor integrated circuit (IC) device comprising:
a first region comprising a first bottom wire, a first top wire, and a first via directly connected to the first bottom wire and directly connected to the first top wire;
a second region comprising a second bottom wire, a second top wire, and a second via directly connected to the second bottom wire and directly connected to the second top wire;
wherein a first vertical dimension between the first bottom wire and the first top wire is greater than a second vertical dimension between the second bottom wire and the second top wire.

12. The semiconductor IC device of claim 11, wherein a top surface of the first top wire is coplanar with a top surface of the second top wire.

13. The semiconductor IC device of claim 12, wherein a bottom surface of the second top wire is below a bottom surface of the first top wire.

14. The semiconductor IC device of claim 13, wherein the second top wire directly contacts a top surface of the second via and directly contacts one or more side surface(s) of the second via.

15. The semiconductor IC device of claim 14, wherein the second top wire wraps around the second via.

16. The semiconductor IC device of claim 11, wherein the first region further comprises one or more additional first top wires with respective bottom surface(s) that are coplanar with a bottom surface of the first top wire.

17. The semiconductor IC device of claim 16, wherein the second region further comprises one or more additional second top wires with respective bottom surface(s) that are coplanar with a bottom surface of the second top wire.

18. The semiconductor IC device of claim 17, wherein a first isolation block separates the first top wire from one or more additional first top wires, the first separation block comprising an first etch stop layer and a first dielectric material upon the first etch stop layer and wherein a second isolation block separates the second top wire from one or more additional second top wires, the second separation block comprising an second etch stop layer and a second dielectric material upon the second etch stop layer.

19. The semiconductor IC device of claim 18, wherein the second etch stop layer is below the first etch stop layer.

20. A semiconductor integrated circuit (IC) device fabrication method comprising:
forming a first bottom wire and a second bottom wire;
forming a first via upon the first bottom wire and forming a second via upon the second bottom wire;
forming a first interlayer dielectric (ILD) upon the first bottom wire and the second bottom wire around the first and second vias;
recessing the first ILD around the second via and maintaining the first ILD around the first via; and
forming a first top wire upon the first via and forming a second top wire wrapped around the second via.

21. The semiconductor integrated circuit (IC) device fabrication method of claim 20, wherein a first vertical dimension between the first bottom wire and the first top wire is greater than a second vertical dimension between the second bottom wire and the second top wire.

22. The semiconductor IC device fabrication method of claim 21, wherein a top surface of the first top wire is coplanar with a top surface of the second top wire.

23. The semiconductor IC device fabrication method of claim 22, wherein a bottom surface of the first top wire is below a bottom surface of the second top wire.

24. A semiconductor integrated circuit (IC) device comprising:
a first region comprising a first bottom wire, a first top wire, and a first via directly connected to a top surface of the first bottom wire and directly connected to a bottom surface of the first top wire; and
a second region comprising a second bottom wire, a second top wire, and a second via directly connected to a bottom surface of the second bottom wire and inset within the second top wire.

25. A semiconductor integrated circuit (IC) device comprising:
a bottom wire level and a top wire level;
a first region a comprising a first bottom wire within the bottom wire level and a first top wire within the top wire level; and
a second region a comprising a second bottom wire within the bottom wire level, a second top wire within the top wire level, and a via connected to the second bottom wire and inset within the second top wire.
